(19) United States
(12) Patent Application Publication
(10) Pub. No.: US 2017/0048623 A1
(43) Pub. Date: Feb. 16, 2017

(54) DUAL BAND MEMS ACOUSTIC DEVICE

(71) Applicant: Knowles Electronics, LLC, Itasca, IL (US)

(72) Inventors: Sarmad Qutub, Des Plaines, IL (US); Max Hamel, Barrington, IL (US)

(73) Assignee: Knowles Electronics, LLC, Itasca, IL (US)

(21) Appl. No.: 15/232,649

(22) Filed: Aug. 9, 2016

Related U.S. Application Data
(60) Provisional application No. 62/203,048, filed on Aug. 10, 2015.

(51) Int. Cl. H04R 19/00; H04R 1/04; B81B 3/00

(52) U.S. Cl. CPC H04R 19/005; B81B 3/0027; H04R 1/04; B81B 2201/0257; B81B 2203/0376; B81B 2203/0127; H04R 2201/003

(57) ABSTRACT

A device includes a first microelectromechanical systems (MEMS) transducer, a second MEMS transducer and a summing device. A first dimension of the first MEMS transducer is predefined to configure the first MEMS transducer to have a first resonance frequency. A second dimension of the second MEMS transducer is predefined to configure the second MEMS transducer to have a second resonance frequency different than the first resonance frequency. The summing device is coupled to the first MEMS transducer and the second MEMS transducer and provides an output representing a combination of information from the first MEMS transducer and the second MEMS transducer.

### CROSS-REFERENCE TO RELATED PATENT APPLICATIONS

This application claims the benefit of and priority to U.S. Provisional Patent Application 62/203,048 filed Aug. 10, 2015 to Qutub et al., titled “Dual Band MEMS Microphone,” the contents of which are incorporated herein by reference in their entirety.

### TECHNICAL FIELD

This application relates to micro electro mechanical system (MEMS) acoustic devices.

### BACKGROUND

Achieving acceptable ultrasonic signal-to-noise ratio (SNR) levels has been challenging in relation to a number of applications. Operating a microphone so as to have an adequate response curve over a frequency range including ultrasonic frequencies has also proved challenging. The problems of previous approaches have resulted in some user dissatisfaction.

### SUMMARY

In one or more embodiments, a microelectromechanical systems (MEMS) acoustic device includes a first MEMS transducer and a second MEMS transducer. The first MEMS transducer includes a first diaphragm and a first back plate. At least one of the first diaphragm and the first back plate has a first dimension. The second MEMS transducer includes a second diaphragm and a second back plate. At least one of the second diaphragm and the second back plate has a second dimension. A magnitude of the second dimension is less than a magnitude of the first dimension.

In one or more embodiments, a device includes a first microelectromechanical systems (MEMS) transducer, a second MEMS transducer and a summing device. A first dimension of the first MEMS transducer is predefined to configure the first MEMS transducer to have a first resonance frequency. A second dimension of the second MEMS transducer is predefined to configure the second MEMS transducer to have a second resonance frequency different than the first resonance frequency. The summing device is coupled to the first MEMS transducer and the second MEMS transducer and provides an output representing a combination of information from the first MEMS transducer and the second MEMS transducer.

The foregoing summary is illustrative and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

For a more complete understanding of the disclosure, reference should be made to the following detailed description and accompanying drawings wherein:

FIG. 1 is a representation of an example MEMS acoustic device according to various embodiments of the present disclosure;

FIG. 2 is a representation of another example MEMS acoustic device according to various embodiments of the present disclosure;

FIG. 3 depicts an example response curve of a MEMS acoustic device according to an embodiment of the present disclosure;

FIG. 4 depicts a top view of a portion of a MEMS acoustic device having two MEMS transducers according to various embodiments of the present disclosure;

FIG. 5 depicts a top view of a portion of a MEMS acoustic device having three MEMS transducers according to various embodiments of the present disclosure; and

FIG. 6 depicts a top view of a portion of a MEMS acoustic device having four MEMS transducers according to various embodiments of the present disclosure.

In the following detailed description, reference is made to the accompanying drawings, which form a part hereof. In the drawings, similar symbols identify similar components. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

### DETAILED DESCRIPTION

As used herein, relative terms, such as “inner,” “interior,” “outer,” “exterior,” “top,” “bottom,” “front,” “back,” “upper,” “upwardly,” “lower,” “downwardly,” “vertical,” “vertically,” “lateral,” “laterally,” “above,” and “below,” refer to an orientation of a set of components with respect to one another; this orientation is in accordance with the drawings, but is not required during manufacturing or use.

The present disclosure describes acoustic devices that include two or more MEMS transducers. The present disclosure further describes acoustic devices which include a first MEMS transducer having a first resonance frequency and a second MEMS transducer having a second resonance frequency different from the first resonance frequency by design. The term “resonance frequency” as used herein refers to a frequency or range of frequencies at which signals oscillate with relatively greater amplitude due to configuration of a device, circuitry, environment, or a combination thereof, such that an amplitude of oscillation at the resonance frequency is greater than an amplitude of oscillation at frequencies other than the resonance frequency.

In the present disclosure, the terms “audible frequency range” and “ultrasonic frequency range” are used. It is to be understood that an “audible frequency range” will vary between subjects (e.g., humans, animals, or other receivers). For example, humans collectively have a human-audible frequency range within a range of about 10 Hertz (Hz) to about 20 kilohertz (kHz), while specific human individuals may have a smaller (and even significantly smaller) audible frequency range within the human-audible frequency range. Thus, references to an audible frequency range herein are intended to be helpful in understanding the concepts described, and are not limiting to one specific range of frequencies. As used herein, the term “ultrasonic frequency range” encompasses frequency ranges of acoustic frequencies above the human-audible frequency range such as, for example, acoustic frequencies above 20 kHz, acoustic frequencies in a range of 20 kHz to 100 kHz, acoustic frequencies in a range of 20 kHz to 2 megahertz (MHz), acoustic frequencies in a range of 50 kHz to 500 kHz, or any other acoustic frequency range above the human-audible frequency range. It should be understood that in some embodiments, an acoustic device may be configured for individuals with hearing capabilities that do not extend to 20 kHz, and an ultrasonic frequency range would accordingly be above an audible frequency range of those individuals.

In one or more embodiments, an acoustic device incorporates a first MEMS transducer for signals in an audible frequency range and a second MEMS transducer for signals in an ultrasonic frequency range. Accordingly, a frequency response of the acoustic device can be improved to be sensitive to audible frequencies and ultrasonic frequencies. In one or more embodiments, the first MEMS transducer is designed to have a resonance frequency in the audible frequency range, and the second MEMS transducer is designed to have a resonance frequency in the ultrasonic frequency range. In one example, the first resonance frequency is designed to be 15 kHz and the second resonance frequency is designed to be 50 kHz. In one or more embodiments, the first MEMS transducer is designed to have a first resonance frequency in the ultrasonic frequency range, such that a frequency response curve of the first MEMS transducer is relatively flat across portions of, or all of, the audible frequency range, and the second MEMS transducer is designed to have a second resonance frequency in the ultrasonic frequency range, where the second resonance frequency is greater than the first resonance frequency. In one example, the first resonance frequency is 30 kHz and the second resonance frequency is 70 kHz.

In one or more embodiments, an acoustic device includes a first MEMS transducer having a first size and a second MEMS transducer having a second size. The term “size” refers to one or more dimensions (e.g., length, width, thickness, area, circumference, radius or volume) of a diaphragm, a back plate, and/or a chamber of a MEMS transducer. In one or more embodiments, an area of the diaphragm and an area of the back plate of the first MEMS transducer is greater than an area of the diaphragm and an area of the back plate of the second MEMS transducer, respectively. This difference in the areas of the diaphragms and the back plates of the first and the second MEMS transducers can result in different resonance frequencies of the first and the second MEMS transducers. For example, the smaller size of the second MEMS transducer results in a resonance frequency that is greater than the resonance frequency of the larger first MEMS transducer.

In one or more embodiments, ultrasonic performance of acoustic devices used in applications such as proximity detection, gesture recognition, activity detection, pen input, and so on, can be improved by including a second MEMS transducer, and may further be improved by combining the advantages of the second MEMS transducer with other ultrasonic performance boosting techniques.

As will be seen from the following discussions related to example embodiments of the present disclosure, MEMS devices can be used as ultrasonic transmitters by leveraging MEMS and package resonances (which can be tuned to ultrasonic frequencies) to maximize output. An ultrasonic MEMS transmitter in conjunction with a dual-band MEMS architecture as discussed herein additionally provides for improvements in (1) ultrasonic sensing, (2) ultrasonic transmission, and (3) ultrasonic proximity detection.

Further, an ability to selectively designate MEMS transducers as transmitters or receivers, combined with multiple MEMS die in a package or multiple MEMS dies on a single substrate, provides for a configurable MEMS architecture for configuration for multiple uses cases. Examples of use cases include enhanced ultrasonic sensing using the MEMS transducers as receivers tuned for ultrasonic signal acquisition, enhanced ultrasonic transmission using the MEMS transducers as transmitters for maximum output/range, and proximity detection with a single package (and/or a single MEMS die with multiple transducers) that can transmit and receive ultrasonic signals for near range proximity.

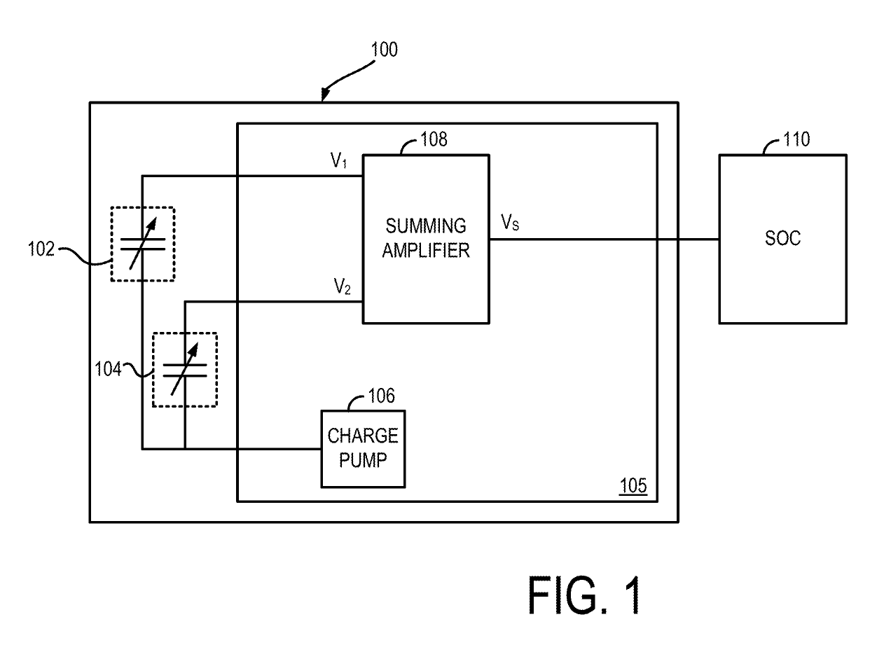

FIG. 1 is a representation of an example of a MEMS microphone device 100 including a first MEMS transducer 102, a second MEMS transducer 104, and a component 105 (e.g., discrete circuitry, a processor, an application specific integrated circuit (ASIC), or a combination thereof). The first MEMS transducer 102 and the second MEMS transducer 104 are illustrated in FIG. 1 as variable capacitance components, reflective of a characteristic of change in capacitance in response to incident acoustic signals. Incident acoustic signals refer to varying sound pressure applied to the first MEMS transducer 102 and the second MEMS transducer 104 resulting from varying frequencies in the sound spectrum propagating to the first MEMS transducer 102 and the second MEMS transducer 104.

The component 105 includes a charge pump 106 and a summing amplifier 108. In one or more embodiments, the charge pump 106 is a direct current (DC) to DC voltage converter. The charge pump 106 is coupled to the first MEMS transducer 102 and the second MEMS transducer 104. In one or more embodiments, the first MEMS transducer 102 and second MEMS transducer 104 can be coupled to separate charge pumps, instead of the same charge pump 106. The charge pump 106 provides power to charge and maintain the first MEMS transducer 102 and the second MEMS transducer 104 at a bias voltage (e.g., the variable capacitances of the first MEMS transducer 102 and the second MEMS transducer 104 are charged to a particular bias voltage in the absence of diaphragm movement). A voltage V₁ at an output of the first MEMS transducer 102 varies as the capacitance of the first MEMS transducer 102 changes responsive to incident acoustic signals, and a voltage V₂ at an output of the second MEMS transducer 104 varies as the capacitance of the second MEMS transducer 104 changes responsive to incident acoustic signals. In other words, the output voltages V₁ and V₂ vary over time as the capacitances of the respective first MEMS transducer 102 and second MEMS transducer 104 vary with the incident acoustic signals, and thus diaphragm movement is translated into an alternating current (AC) signal superimposed over the bias voltage. The output voltages V₁ and V₂ are provided to the summing amplifier 108. In one or more embodiments, the output voltages V₁ and V₂ may be filtered or buffered prior to being provided to the summing amplifier 108 (e.g., to filter out ripple from the charge pump, or to average out unwanted noise).

The summing amplifier 108 adds the voltage outputs V₁ and V₂ of the first and the second MEMS transducers 102 and 104, respectively, and outputs a summed output voltage Vₛ. The summing amplifier 108 can include, for example, a summing operational amplifier, an instrumentation amplifier, a differential amplifier, or two or more thereof. In one or more embodiments, the summing amplifier 108 can have unity gain. The output voltage Vₛ of the summing amplifier 108 is provided to a controller 110 (e.g., shown by way of example as a system on chip (SoC)). In one or more embodiments, the controller 110 can be implemented, without limitation, using a microprocessor, a multi-core processor, a digital signal processor, an ASIC, a field programmable gate array (FPGA), or other control device and associated circuitry. In one or more embodiments, the component 105 can include an analog to digital converter (ADC) to digitize the summed output voltage Vₛ. Alternatively, the controller 110 can include an ADC to digitize the summed output voltage Vₛ. The digitized summed output voltage can be processed by the controller 110. For example, in one or more embodiments, processing carried out by the controller 110 can include identifying a word or phrase, or identifying an ultrasonic frequency pattern. In one or more other embodiments, processing can further include, without limitation, filtering, determining impulse response, sampling and signal reconstruction, frequency analysis, and power spectrum estimation.

The first MEMS transducer 102 includes a first diaphragm and a first back plate. Similarly, the second MEMS transducer 104 includes a second diaphragm and a second back plate. In one or more embodiments, the first back plate and the second back plate are coupled to the summing amplifier 108, while the first diaphragm and the second diaphragm are coupled to the charge pump 106. In one or more other embodiments, the first back plate and the second back plate are coupled to the charge pump 106, while the first diaphragm and the second diaphragm are coupled to the summing amplifier 108.

In one or more embodiments, surface areas of the first back plate and the first diaphragm of the first MEMS transducer 102 are approximately the same. In one or more other embodiments, the surface area of the first back plate can be different from the surface area of the first diaphragm. In one or more embodiments, surface areas of the second back plate and the second diaphragm of the second MEMS transducer 104 are approximately the same. In one or more other embodiments, the surface area of the second back plate can be different from the surface area of the second diaphragm.

In one or more embodiments, the surface areas of the first back plate and the first diaphragm of the first MEMS transducer 102 are substantially greater by design than surface areas of, respectively, the second back plate and the second diaphragm of the second MEMS transducer 104; such as, for example two to three times greater.

In general terms, when a MEMS transducer is positioned within an acoustic device, the acoustic device has a geometric front volume defined between a first side of the transducer (closest to the diaphragm) and a portion of the acoustic device that includes a port corresponding to the transducer (such as a printed circuit board with a port hole faced by the transducer in a bottom port configuration, or such as a housing with a port hole faced by the transducer in a top port configuration). Thus, the front volume is a function of a surface area of the first side of the transducer facing the port (in either the top port configuration or the bottom port configuration). The acoustic device also has a geometric back volume defined between an opposite second side of the transducer (closest to the back plate) and a portion of the acoustic device opposite the port corresponding to the transducer (e.g., a side of the housing (e.g., a can) of the acoustic device in the bottom port configuration or in the printed circuit board in the top port configuration). A resonance frequency of the transducer is inversely related to a ratio of the front and back volumes. Because the front volume is a function of the surface area of the first side of the transducer, and because generally the surface area of the first side of the transducer is defined in large part by the sizes of the back plate and the diaphragm within the transducer, the front volume is a function of the surface areas of the back plate and the diaphragm. Thus, for a defined distance between the transducer and the port, a decrease in the surface areas of the back plate and the diaphragm will result in a decrease in the front volume and a corresponding increase in the resonance frequency.

Referring back to FIG. 1, in embodiments in which the surface areas of the back plate and diaphragm of the first MEMS transducer 102 are larger than the surface areas of the back plate and diaphragm of the second MEMS transducer 104, the resonance frequency of the first MEMS transducer 102 is less than the resonance frequency of the second MEMS transducer 104. In one non-limiting example, the resonance frequency of the first MEMS transducer 102 is about 25 kHz while the resonance frequency of the second MEMS transducer (with relatively smaller surface areas) is about 50 kHz to about 60 kHz. In one or more embodiments, the second MEMS transducer 104 is capable of sensing a wide range of frequencies, but is optimized to sense signals in an ultrasonic frequency range, such as signals in a frequency range of about 30 kHz to about 100 kHz. In one or more embodiments, the first MEMS transducer 102 is capable of sensing a wide range of frequencies, but is optimized to sense signals in a human-audible frequency band, such as signals in a frequency range of 10 Hz to 20 kHz.

In addition to being related to a relationship between the front and back volumes, the resonance frequency of a MEMS transducer is a function of a thickness of the diaphragm. In particular, the resonance frequency of the MEMS transducer can increase with an increase in the thickness of the diaphragm. In one or more embodiments, the first MEMS transducer 102 and the second MEMS transducer 104 may have similar surface areas but different diaphragm thicknesses, resulting in different respective resonance frequencies. In one or more embodiments, the diaphragm of the second MEMS transducer 104 is thicker than the diaphragm of the first MEMS transducer 102, such that the resonance frequency of the second MEMS transducer 104 is in the ultrasonic frequency range, while the resonance frequency of the first MEMS transducer 102 is in the audible frequency range.

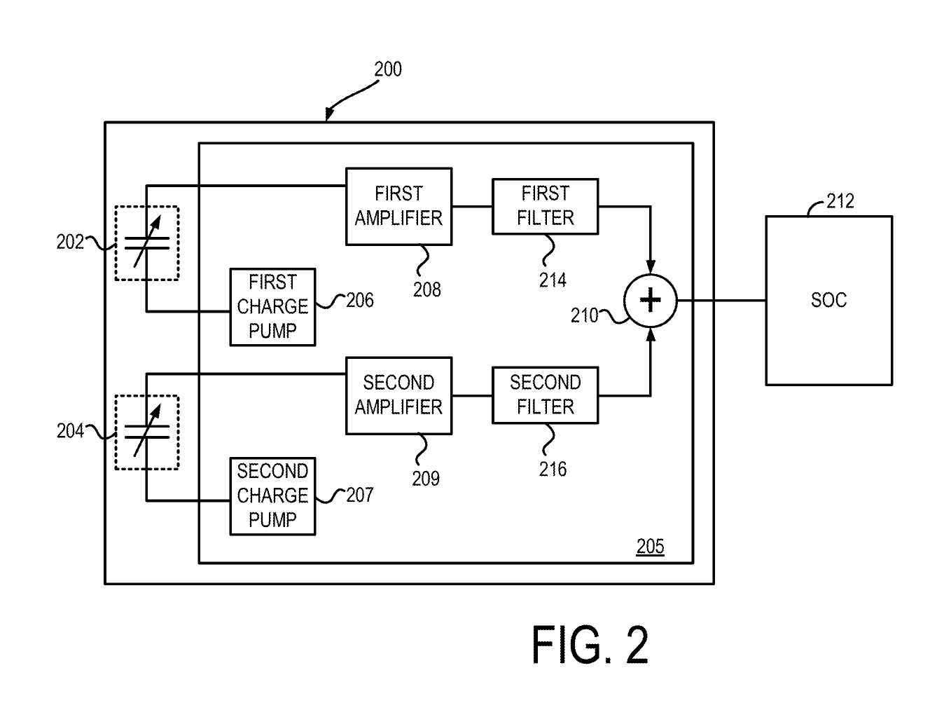

FIG. 2 is a representation of an example of a microphone device 200 including a first MEMS transducer 202 and a second MEMS transducer 204 coupled to a component 205 (e.g., discrete circuitry, a processor, an ASIC, or a combination thereof). The first MEMS transducer 202 and the second MEMS transducer 204 are similar to the first MEMS transducer 102 and the second MEMS transducer 104, respectively.

The component 205 includes a first charge pump 206 and a second charge pump 207, which can be similar in design and operation to the charge pump 106 of FIG. 1. In one or more embodiments, a single charge pump, rather than two separate charge pumps (the first charge pump 206 and the second charge pump 207), can be used to supply power to the first MEMS transducer 202 and the second MEMS transducer 204.

The component 205 further includes a first amplifier 208, a second amplifier 209, an adder 210, a first filter 214, and a second filter 216. An output of the first MEMS transducer 202 is coupled to the first amplifier 208, while an output of the second MEMS transducer 204 is coupled to the second amplifier 209. An output of the first amplifier 208 is coupled to the first filter 214, and an output of second amplifier 209 is coupled to the second filter 216. Outputs of the first filter 214 and the second filter 216 are coupled to the adder 210. An output of the adder 210 is coupled to a controller 212 (e.g., shown by way of example as a system on chip (SoC)). In one or more embodiments, the controller 212 can be implemented, without limitation, using a microprocessor, a multi-core processor, a digital signal processor, an ASIC, an FPGA, or other control device and associated circuitry.

The adder 210 can be similar to the summing amplifier 108 discussed above in relation to FIG. 1. In one or more embodiments, the adder 210 can have unity gain. In one or more embodiments, the controller 212 can be similar to the controller 110 discussed above in relation to FIG. 1.

The first amplifier 208 and the second amplifier 209 amplify signals received from the first MEMS transducer 202 and the second MEMS transducer 204, respectively.

One or both of the first filter 214 and the second filter 216 may filter unwanted noise from the respective received signals. In one or more embodiments, one or both of the first filter 214 and the second filter 216 filter out signal information in frequencies not in a range of interest. For example, if it is desired that signals received from the first amplifier 208 are to be limited to human-audible frequencies, the first filter 214 may filter out ultrasonic frequencies. For another example, if it is desired that signals received from the second amplifier 209 are to be limited to ultrasonic frequencies, the second filter 216 may filter out human-audible frequencies. For a further example, the first filter 214 may filter out frequencies below a human-audible range, and/or the second filter 216 may filter out frequencies above an ultrasonic frequency of interest. Thus, the first filter 214 and the second filter 216 may include lowpass, highpass, bandpass, or bandstop filters, or any combination thereof. In one or more embodiments, one or both of the first filter 214 and the second filter 216 may average or integrate received signals over specified time periods, such as to reduce noise. In one or more embodiments, one or both of the first filter 214 and the second filter 216 may be omitted.

The adder 210 sums or adds the two filtered signals together to generate a summed signal provided to the controller 212.

Similarly as discussed with respect to the first MEMS transducer 102 and the second MEMS transducer 104 in FIG. 1, dimensions of the first MEMS transducer 202 and the second MEMS transducer 204 may differ. For example, back plate and/or diaphragm surface areas may differ, or diaphragm thicknesses may differ. Thus, resonance frequencies of the first MEMS transducer 202 and the second MEMS transducer 204 can be designed to differ, as discussed above. Accordingly, in one or more embodiments, the resonance frequency of the first MEMS transducer 202 can be about 3 kHz and the resonance frequency of the second MEMS transducer 204 can be about 50 to about 60 kHz. In one or more embodiments, the second MEMS transducer 104 is capable of sensing a wide range of frequencies, but is optimized to sense signals in an ultrasonic frequency range, such as signals in the frequency range of 30 kHz to 100 kHz, and the first MEMS transducer 102 is capable of sensing a wide range of frequencies, but is optimized to sense signals in an audible frequency band, such as signals in a frequency range of 10 Hz to 20 kHz.

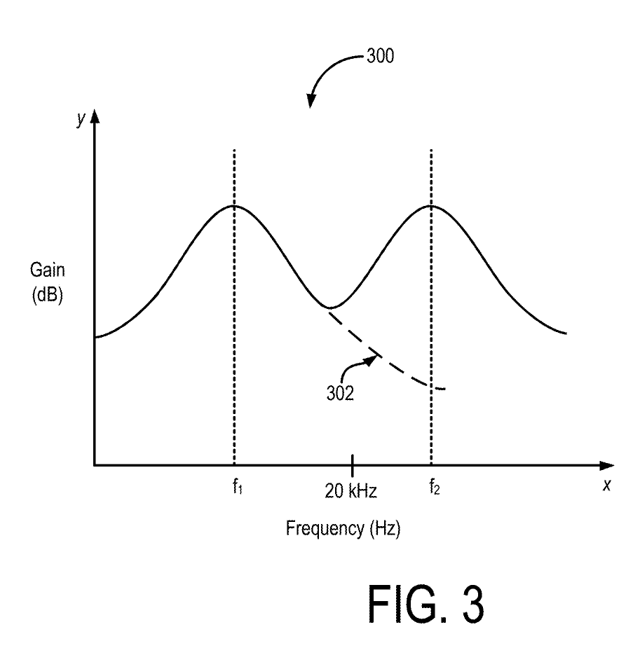

FIG. 3 depicts an example frequency response curve 300 of a microphone device (e.g., the microphone device 100 of FIG. 1 or the microphone device 200 of FIG. 2). Frequency is shown along the x-axis, and a magnitude of a frequency response is shown along the y-axis. The frequency response curve 300 includes two peaks, each corresponding to a resonance frequency of a MEMS transducer. For example, a first frequency f₁ represents a resonance frequency of a first MEMS transducer (e.g., the first MEMS transducer 102 in FIG. 1 or the first MEMS transducer 202 in FIG. 2). A second frequency f₂ represents a resonance frequency of a second MEMS transducer (e.g., the second MEMS transducer 104 in FIG. 1 or the second MEMS transducer 204 in FIG. 2). The first resonant frequency f₁ is in an audible frequency range, such as frequencies between about 10 Hz to about 20 kHz. In one or embodiments, the first frequency f₁ is about 3 kHz. The second frequency f₂ is in an ultrasonic frequency range, such as frequencies above 20 kHz. In one or more embodiments, the second frequency f₂ is about 50 kHz to about 60 kHz.

FIG. 3 also indicates an example of a frequency response of an acoustic device if the acoustic device were to omit the second MEMS transducer (e.g., the first MEMS transducer 102 or 202) having a resonance frequency f₂ in the ultrasonic frequency range. As indicated by the dotted line 302, the first MEMS transducer alone would attenuate frequencies in the ultrasonic frequency range (e.g., frequencies above 20 kHz), resulting in an unsatisfactory operation of the acoustic device in the ultrasonic frequency range. However, including the second MEMS transducer (e.g., the second MEMS transducer 104 or 204) with a resonance frequency f₂ in the ultrasonic frequency range and summing the output signals of the first MEMS transducer and the second MEMS transducer results in a frequency response where frequencies in the ultrasonic frequency range are relatively amplified.

Although the foregoing discussion was with respect to two MEMS transducers, additional MEMS transducers may be included in an acoustic device according to the present disclosure, to further shape a desired frequency response.

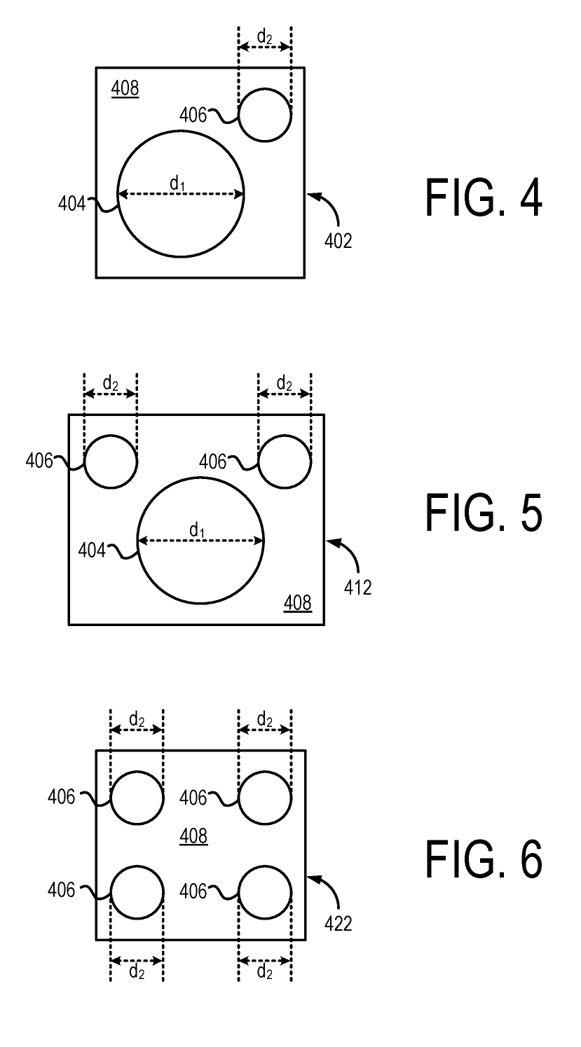

FIGS. 4-6 illustrate examples of various acoustic devices that include multiple MEMS transducers. In each of FIGS. 4-6, first MEMS transducers 404 and second MEMS transducers 406 are similar to, and can be operated in a manner similar to, that discussed above in relation to the first MEMS transducer 102 and the second MEMS transducer 104, respectively, in FIG. 1, or the first MEMS transducer 202 and the second MEMS transducer 204, respectively, in FIG. 2. As illustrated in FIGS. 4-6, the first MEMS transducer 404 has a diameter d₁, while the second MEMS transducer 406 has a diameter d₂, where d₁ is greater than d₂. The diameters d₁, d₂ refer to diameters of respective diaphragms and/or back plates. As the diameter d₁ of the first MEMS transducer 404 is greater than the diameter d₂ of the second MEMS transducer 406, a resonance frequency of the first MEMS transducer 404 is less than a resonance frequency of the second MEMS transducer 406. For example, in one or more embodiments, the resonance frequency of the first MEMS transducer 404 can be in an audible frequency range, such as frequencies between about 10 Hz to about 20 kHz, and the resonance frequency of the second MEMS transducer 406 can be in an ultrasonic frequency range, such as frequencies above about 20 kHz.

Also in FIGS. 4-6, a substrate 408 is illustrated. The substrate 408 can be, for example, a semiconductor substrate or a printed circuit board.

It is to be understood that the acoustic devices of FIGS. 4-6 are provided by way of illustration and are not limiting. Any combination or arrangement of first MEMS transducers 404 and second MEMS transducers 406 are within the scope of the present disclosure. Further, it is to be understood that other acoustic devices are within the scope of the present disclosure, such as acoustic devices further incorporating one or more MEMS transducers having a diameter d₃ of a back plate and/or diaphragm, where d₃ may be less than or greater than d₁ and less than or greater than d₂. Indeed, an acoustic device according to embodiments of the present disclosure may incorporate any number of MEMS transducers, in which each of the MEMS transducers may have a same or a different diameter of back plate and/or diaphragm than others of the MEMS transducers.

FIG. 4 illustrates a top view of an example acoustic device 402 including a first MEMS transducer 404 and a second MEMS transducer 406 disposed on a same substrate 408.

FIG. 5 illustrates an acoustic device 412 having one first MEMS transducer 404 and two second MEMS transducers 406 disposed on a same substrate 408.

FIG. 6 shows an acoustic device 422 including four second MEMS transducers 406 disposed on the same substrate 408.

Although illustrated in FIGS. 4-6 as sharing a substrate 408, one or more of the first MEMS transducers 404 or the second MEMS transducers 406 may be disposed on a separate substrate.

Although described above with respect to receiving incident signals, any of the MEMS transducers (e.g., any of the first MEMS transducers 102, 202, 404 or the second MEMS transducers 104, 204, 406) may be used alternatively or additionally to transmit signals. For example, with respect to FIG. 5 or FIG. 6, in one mode of operation, one of the second MEMS transducers 406 may transmit ultrasonic signals and another of the second MEMS transducers 406 may receive ultrasonic signals, or, one or both of the second MEMS transducers 406 may transmit ultrasonic signals during one time period and receive ultrasonic signals in another time period. For another example, with respect to FIG. 4 or FIG. 5, the first MEMS transducer 404 may be configured to transmit human-audible signals, receive human-audible signals, or transmit human-audible signals during one time period and receive human-audible signals in another time period. Transmission or reception may be controlled by a computing device, such as the controller 110 in FIG. 1 or the controller 212 in FIG. 2.

While the shape of each of the first and the second MEMS transducers 404 and 406 shown in FIGS. 4-6 is substantially circular, other shapes are also possible, such as rectangular, hexagonal, elliptical, irregular, and other shapes.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

As used herein, the singular terms “a,” “an,” and “the” may include plural referents unless the context clearly dictates otherwise.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A microelectromechanical systems (MEMS) acoustic device, comprising:
a first MEMS transducer including a first diaphragm and a first back plate, wherein at least one of the first diaphragm and the first back plate has a first dimension; and
a second MEMS transducer including a second diaphragm and a second back plate, wherein at least one of the second diaphragm and the second back plate has a second dimension, and wherein a magnitude of the second dimension is less than a magnitude of the first dimension.

2. The MEMS acoustic device of claim 1, wherein the first dimension and the second dimension refer to a length, width, radius, thickness, area, or circumference.

3. The MEMS acoustic device of claim 1, wherein the first MEMS transducer has a first resonance frequency and the second MEMS transducer has a second resonance frequency that is higher than the first resonance frequency.

4. The MEMS acoustic device of claim 3, wherein the first resonance frequency is a human-audible frequency and the second resonance frequency is an ultrasonic frequency.

5. The MEMS acoustic device of claim 3, wherein the first resonance frequency is a first ultrasonic frequency and the second resonance frequency is a second ultrasonic frequency.

6. The MEMS acoustic device of claim 1, further comprising a charge pump coupled to the first MEMS transducer and the second MEMS transducer, wherein the charge pump provides power to the first MEMS transducer and the second MEMS transducer.

7. The MEMS acoustic device of claim 6, further comprising a summing amplifier coupled to the first MEMS transducer and the second MEMS transducer, the summing amplifier configured to generate a summed electrical signal based on a first electrical signal output by the first MEMS transducer and a second electrical signal output by the second MEMS transducer.

8. The MEMS acoustic device of claim 1, further comprising:
a first charge pump coupled to the first MEMS transducer, the first charge pump configured to provide power to the first MEMS transducer;
a second charge pump coupled to the second MEMS transducer, the second charge pump configured to provide power to the second MEMS transducer;

9. The MEMS acoustic device of claim 1, further comprising:
a charge pump coupled to the first MEMS transducer and the second MEMS transducer, the charge pump configured to provide power to the first MEMS transducer and the second MEMS transducer.

10. The MEMS acoustic device of claim 1, further comprising:
a first amplifier coupled to the first MEMS transducer, the first amplifier configured to amplify an electrical signal output by the first MEMS transducer to output a first amplified signal;
a second amplifier coupled to the second MEMS transducer; the second amplifier configured to amplify an electrical signal output by the second MEMS transducer to output a second amplified signal; and
a summer coupled to the first amplifier and the second amplifier, the summer configured to output a summed electrical signal based on a sum of the first amplified signal and the second amplified signal.

11. The MEMS acoustic device of claim 10, wherein the first amplifier, the second amplifier, or the first amplifier and the second amplifier have unity gain.

12. The MEMS acoustic device of claim 1, wherein one of the first MEMS transducer and the second MEMS transducer is configured as a transmitter and the other of the first MEMS transducer and the second MEMS transducer is configured as a receiver.

13. The MEMS acoustic device of claim 1, further comprising:
a third MEMS transducer, the third MEMS transducer including a third diaphragm and a third back plate, wherein at least one of the third diaphragm and the third back plate has a third dimension.

14. The MEMS acoustic device of claim 13, wherein a magnitude of the third dimension is equal to the magnitude of the second dimension.

15. The MEMS acoustic device of claim 14, wherein the third MEMS transducer has a third resonance frequency that is substantially equal to the second resonance frequency.

16. The MEMS acoustic device of claim 13, wherein one of the first MEMS transducer and the third MEMS transducer is configured as a transmitter and the other of the first MEMS transducer and the third MEMS transducer is configured as a receiver.

17. A device, comprising:
a first microelectromechanical systems (MEMS) transducer, a first dimension of the first MEMS transducer predefined to configure the first MEMS transducer to have a first resonance frequency;
a second MEMS transducer, a second dimension of the second MEMS transducer predefined to configure the second MEMS transducer to have a second resonance frequency different than the first resonance frequency; and
a summing device coupled to the first MEMS transducer and the second MEMS transducer and configured to provide an output representing a combination of information from the first MEMS transducer and the second MEMS transducer.

18. The device of claim 17, wherein the first resonance frequency is within a range of human-audible frequencies.

19. The device of claim 17, wherein the first resonance frequency is within a range of ultrasonic frequencies.

20. The device of claim 17, wherein the second resonance frequency is within a range of ultrasonic frequencies.

21. The device of claim 17, wherein the first dimension is a surface area of a diaphragm of the first MEMS transducer, or wherein the second dimension is a surface area of a diaphragm of the second MEMS transducer.

22. The device of claim 17, wherein the first dimension is a thickness of a diaphragm of the first MEMS transducer, or wherein the second dimension is a thickness of a diaphragm of the second MEMS transducer.

23. The device of claim 17, wherein the summing device is a summing amplifier, and the output from the summing device is a sum of the information from the first MEMS transducer and the second MEMS transducer.

24. The device of claim 17, wherein the summing device comprises a first amplifier coupled to the first MEMS transducer, a second amplifier coupled to the second MEMS transducer, and an adder coupled to the first amplifier and the second amplifier and configured to output a signal representing a sum of an output from the first amplifier and an output of the second amplifier.

25. The device of claim 24, further comprising a first filter coupled between the first amplifier and the adder, and a second filter coupled between the second amplifier and the adder, wherein one or both of the first filter and the second filter is an averaging filter.

26. The device of claim 17, further comprising a substrate, wherein the first MEMS transducer and the second MEMS transducer are disposed on the substrate.

27. The device of claim 17, further comprising at least two substrates, wherein the first MEMS transducer is disposed on a first substrate of the two substrates and the second MEMS transducer is disposed on a second substrate of the two substrates.
